(19) United States
(12) Patent Application Publication
(10) Pub. No.: US 2021/0109271 A1
(43) Pub. Date: Apr. 15, 2021

(54) IMAGE DISPLAY DEVICE

(71) Applicant: NITTO DENKO CORPORATION, Ibaraki-shi, Osaka (JP)

(72) Inventors: Hiroshi Tomohisa, Ibaraki-shi (JP); Hironori Yaginuma, Ibaraki-shi (JP); Ryoji Kinoshita, Ibaraki-shi (JP)

(73) Assignee: NITTO DENKO CORPORATION, Ibaraki-shi, Osaka (JP)

(21) Appl. No.: 16/498,538

(22) PCT Filed: Jan. 4, 2018
(86) PCT No.: PCT/JP2018/000010

§ 371 Date: Sep. 27, 2019

(30) Foreign Application Priority Data
Mar. 30, 2017 (JP) 2017-066855

(51) Int. Cl. G02B 5/30; G02B 27/00; H01L 51/52

(52) U.S. Cl. CPC G02B 5/3083; H01L 51/5281; G02B 27/0006

(57) ABSTRACT

An image display apparatus is disclosed including a display cell, a first retardation layer, a second retardation layer, and a polarizer. Re(550) of a laminate of the first retardation layer and the second retardation layer is from 120 nm to 142 nm, or from 151 nm to 160 nm, and when an initial value of a front reflection hue value “a” in a non-lit state is represented by a₀, a value of “a” after the image display apparatus is left in an environment set to 65° C. and an RH of 90% for 250 hours is represented by a₁, an initial value of a front reflection hue value “b” is represented by b₀, and a value of “b” after the image display apparatus is left in an environment set to 65° C. and an RH of 90% for 250 hours is represented by b₁, a₀×a₁>0 and b₀×b₁>0 are satisfied.

### TECHNICAL FIELD

The present invention relates to an image display apparatus.

### BACKGROUND ART

In recent years, image display apparatus typified by a liquid crystal display apparatus and an organic electroluminescence (EL) display apparatus have been rapidly gaining more widespread use. In the image display apparatus, a polarizing plate and a retardation plate are typically used. In practical use, a polarizing plate with a retardation layer, in which the polarizing plate and the retardation plate are integrated, is widely used (for example, Patent Literature 1). The image display apparatus of the related art, however, have a problem in that color unevenness in which a perimeter portion of the image display apparatus assumes a tint of red occurs in a high-temperature and high-humidity environment.

### CITATION LIST

### Patent Literature

[PTL 1] JP 3325560 B2

### SUMMARY OF INVENTION

### Technical Problem

The present invention has been made to solve the conventional problem as described above, and a main object of the present invention is to provide an image display apparatus on which a change in reflection hue in a high-temperature and high-humidity environment is unnoticeable.

### Solution to Problem

An image display apparatus according to an embodiment of the present invention includes a display cell, a first retardation layer, a second retardation layer, and a polarizer, which are arranged in the stated order. Re(550) of a laminate of the first retardation layer and the second retardation layer is from 120 nm to 142 nm, or from 151 nm to 160 nm, and when an initial value of a front reflection hue value “a” in a non-lit state is represented by a₀, a value of “a” after the image display apparatus is left in an environment set to 65° C. and an RH of 90% for 250 hours is represented by a₁, an initial value of a front reflection hue value “b” is represented by b₀, and a value of “b” after the image display apparatus is left in an environment set to 65° C. and an RH of 90% for 250 hours is represented by b₁, Expressions (1) and (2) are satisfied:

a₀×a₁>0 (1); and

b₀×b₁>0 (2).

In one embodiment of the present invention, the image display apparatus further includes a moisture-barrier layer on one side of the polarizer that is opposite from the second retardation layer.

In one embodiment of the present invention, when a value of the value “a” after the image display apparatus is left in an environment set to 85° for 250 hours is represented by a₂, and a value of the value “b” after the image display apparatus is left in an environment set to 85° for 250 hours is represented by b₂, Expressions (3) and (4) are satisfied:

a₀×a₂>0 (3); and

b₀×b₂>0 (4).

In one embodiment of the present invention, the value a₀ is from −10.00 to −1.00, or from 1.00 to 10.00, and the value b₀ is from −10.00 to −1.50, or from −0.20 to 10.00.

In one embodiment of the present invention, the first retardation layer shows a refractive index characteristic of nz>nx≥ny, and the second retardation layer shows a refractive index characteristic of nx>ny≥nz.

In one embodiment of the present invention, the image display apparatus is an organic electroluminescence display apparatus.

### Advantageous Effects of Invention

According to the present invention, the image display apparatus on which color unevenness in a high-temperature and high-humidity environment is unnoticeable is achieved by setting an initial reflection hue in the image display apparatus to a hue shifted toward blue or red.

### BRIEF DESCRIPTION OF DRAWINGS

FIG. 1 is a schematic sectional view of an image display apparatus according to an embodiment of the present invention.

FIG. 2 is a schematic sectional view of an organic EL cell to be used for an organic EL display apparatus according to the embodiment of the present invention.

### DESCRIPTION OF EMBODIMENTS

Embodiments of the present invention are described below. However, the present invention is not limited to these embodiments.

### Definitions of Terms and Symbols

The definitions of terms and symbols used herein are as described below.

### (1) Refractive Indices (nx, ny, and nz)

“nx” represents a refractive index in a direction in which an in-plane refractive index is maximum (that is, slow axis direction), “ny” represents a refractive index in a direction perpendicular to the slow axis in the plane (that is, fast axis direction), and “nz” represents a refractive index in a thickness direction.

### (2) In-Plane Retardation (Re)

“Re(λ)” refers to an in-plane retardation measured at 23° C. with light having a wavelength of λ nm. For example, “Re(550)” refers to an in-plane retardation measured at 23° C. with light having a wavelength of 550 nm. The Re(λ) is determined from the equation “Re(λ)=(nx−ny)×d” when the thickness of a layer (film) is represented by d (nm).

### (3) Thickness Direction Retardation (Rth)

“Rth(λ)” refers to a thickness direction retardation measured at 23° C. with light having a wavelength of λ nm. For example, “Rth(550)” refers to a thickness direction retardation measured at 23° C. with light having a wavelength of 550 nm. The Rth(λ) is determined from the equation “Rth(λ)=(nx−nz)×d” when the thickness of a layer (film) is represented by d (nm).

### (4) Nz Coefficient

An Nz coefficient is determined from the equation “Nz=Rth/Re”.

A. Overall Configuration of Image Display Apparatus

An image display apparatus according to one embodiment of the present invention includes a display cell, a first retardation layer, a second retardation layer, and a polarizer, which are arranged in the stated order. Re(550) of a laminate of the first retardation layer and the second retardation layer is from 120 nm to 142 nm, or from 151 nm to 160 nm. In the image display apparatus according to the present invention, when an initial value of a front reflection hue value “a” in a non-lit state of the image display apparatus is represented by a₀, a value of “a” after the image display apparatus is left in an environment set to 65° C. and an RH of 90% for 250 hours is represented by a₁, an initial value of a front reflection hue value “b” is represented by b₀, and a value of “b” after the image display apparatus is left in an environment set to 65° C. and an RH of 90% for 250 hours is represented by b₁, Expressions (1) and (2) are satisfied:

a₀×a₁>0 (1); and

b₀×b₁>0 (2).

In one embodiment, in the image display apparatus, when a value of the value “a” after the image display apparatus is left in an environment set to 85° for 250 hours is represented by a₂, and a value of the value “b” after the image display apparatus is left in an environment set to 85° for 250 hours is represented by b₂, Expressions (3) and (4) are further satisfied:

a₀×a₂>0 (3); and

b₀×b₂>0 (4).

In the image display apparatus according to the present invention, the value a₀ is preferably from −10.00 to −1.00, or from 1.00 to 10.00, and the value b₀ is preferably from −10.00 to −1.50, or from −0.20 to 10.00. When the image display apparatus is placed in a high-temperature and high-humidity environment, Expressions (1) to (4) are satisfied by setting a₀ and b₀ to values within these ranges. The amount of change in reflection hue caused when the image display apparatus is placed in a high-temperature and high-humidity environment may be taken into consideration in setting each of a₀ and b₀. The value of a₀ is more preferably −1.50 or less, still more preferably −2.00 or less. In this case, a lower limit of a₀ is preferably −8.00. Alternatively, the value of a₀ is more preferably 1.20 or more, still more preferably 1.40 or more. In this case, an upper limit of a₀ is preferably 8.00. The value of b₀ is more preferably −1.70 or less, still more preferably −2.00 or less. In this case, a lower limit of b₀ is preferably −8.00. Alternatively, the value of b₀ is more preferably −0.15 or more, still more preferably −0.10 or more. In this case, an upper limit of b₀ is preferably 8.00.

The feature described above typically corresponds to setting an initial reflection hue in the image display apparatus to a hue shifted toward blue or red. This is a design concept completely opposite to the design concept in the art. More specifically, whereas the initial reflection hue in a normal image display apparatus is set to be as colorless as possible (set to be neutral), the initial reflection hue in the image display apparatus according to the present invention is set to a hue deliberately shifted toward blue or red. This yields an advantage given below. An image display apparatus sometimes develops color unevenness, particularly in a perimeter portion, at high temperature and high humidity. The color unevenness is recognized typically by a change in reflection hue from blue toward red. In an image display apparatus in which the initial reflection hue is set as neutral as possible, the initial reflection hue is naturally in a favorable state but, once the reflection hue changes toward red under a high-temperature and high-humidity environment, color unevenness that is very noticeable to viewers develops. Specifically, a perimeter portion of the image display apparatus assumes a tint of red, which is very conspicuous when a neutral hue is the reference. According to the present invention, on the other hand, in an embodiment in which the initial reflection hue is shifted toward blue, a change in reflection hue toward red in a high-temperature and high-humidity environment is within a range in which the hue is still recognized as blue, and is accordingly unnoticeable to viewers. Similarly, in an embodiment in which the initial reflection hue is shifted toward red, a change in reflection hue toward red in a high-temperature and high-humidity environment is within a range in which the hue is still recognized as red, and is accordingly unnoticeable to viewers as well. In short, the image display apparatus according to the present invention is capable of making the same absolute amount of change in reflection hue in a high-temperature and high-humidity environment less noticeable than in a general image display apparatus.

The present invention is applicable to any appropriate image display apparatus that has the feature described above. Typical examples of an image display apparatus include organic electroluminescence (EL) display apparatus, liquid crystal display apparatus, and quantum dot display apparatus. An organic EL display apparatus is described below as an example, but it is obvious to a person skilled in the art that the present invention is applicable to other image display apparatus as well. Configurations known in the art can be employed for items that are related to the configuration of the image display apparatus and that are not described herein.

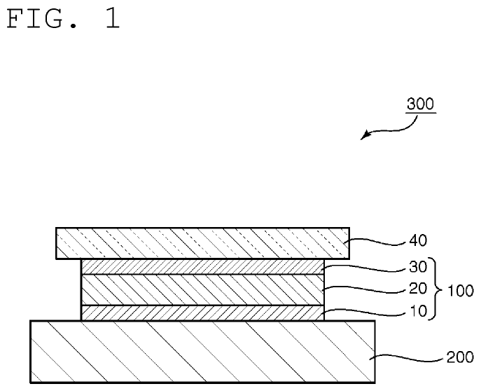

FIG. 1 is a schematic sectional view of an organic EL display apparatus according to an embodiment of the present invention. An organic EL display apparatus 300 of the illustrated example includes an organic EL cell 200, and includes a first retardation layer 10, a second retardation layer 20, and a polarizer 30, which are arranged in order from the organic EL cell 200 side on the viewer side of the organic EL cell 200. The first retardation layer 10, the second retardation layer 20, and the polarizer 30 may sequentially be laminated on the organic EL cell, or may be unitarily formed (as a polarizing plate 100 with a retardation layer) to be laminated on the organic EL cell. Typically, the polarizing plate 100 with a retardation layer is laminated on the organic EL cell 200. A protective layer (not shown) may be placed on at least one side of the polarizer 30. For instance, one or both of a viewer-side protective layer and an inner protective layer may be placed.

The organic EL display apparatus 300 preferably further includes a moisture-barrier layer 40 on one side of the polarizer 30 that is opposite from the second retardation layer 20 (typically as the outermost layer). The moisture-barrier layer is, for example, cover glass or a cover film. The effect of the present invention is prominent when the moisture-barrier layer is present. Specifically, the presence of the moisture-barrier layer increases a difference in water absorption ratio between the perimeter portion and a central portion, thereby accentuating phase difference unevenness (ultimately color unevenness) in the perimeter portion. The present invention is capable of preventing such color unevenness well as described above.

A specific description is given below of components of the image display apparatus. Layers and optical films that form the image display apparatus are laminated via any appropriate adhesion layers (e.g., pressure-sensitive adhesive layers or adhesive layers), unless otherwise particularly noted.

B. Organic EL Cell

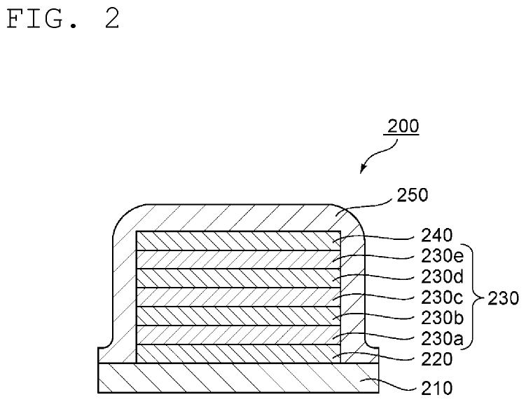

Any appropriate organic EL cell is employable as the organic EL cell 200 as long as the effect of the present invention is obtained. FIG. 2 is a schematic sectional view for illustrating a mode of the organic EL cell to be used in the present invention. The organic EL cell 200 typically includes a substrate 210, a first electrode 220, an organic EL layer 230, and a second electrode 240, as well as a sealing layer 250, which covers these components. The organic EL cell 200 may further include any appropriate layer as required. For instance, a planarization layer (not shown) may be formed on the substrate, and an insulating layer (not shown) for preventing a short circuit may be formed between the first electrode and the second electrode.

The substrate 210 may be made from any appropriate material. The material of the substrate 210 preferably has a barrier property. The substrate made from this material is capable of protecting the organic EL layer 230 from oxygen and moisture. The substrate 210 is typically made of glass. In one embodiment, the substrate 210 may be made from a flexible material. When the polarizing plate with a retardation layer that has an elongate shape is used, a flexible substrate allows the organic EL display apparatus to be manufactured by what is called a roll-to-roll process, and low cost and mass production are accordingly accomplished. Specific examples of the material having a barrier property and flexibility include a thin glass having imparted thereto flexibility, a thermoplastic resin or thermosetting resin film having imparted thereto a barrier property, an alloy, and a metal. Examples of the alloy include stainless steel, 36 alloy, and 42 alloy. Examples of the metal include copper, nickel, iron, aluminum, and titanium. The substrate has a thickness of preferably from 5 μm to 500 μm, more preferably from 5 μm to 300 μm, still more preferably from 10 μm to 200 μm.

The first electrode 220 typically functions as an anode. In this case, a material having a high work function value is preferred as the material of the first electrode from the viewpoint of facilitating hole injection. Specific examples of this material include: transparent conductive materials, such as indium tin oxide (ITO), indium zinc oxide (IZO), indium tin oxide (ITSO) having added thereto silicon oxide, indium oxide (IWO) containing tungsten oxide, indium zinc oxide (IWZO) containing tungsten oxide, indium oxide (ITiO) containing titanium oxide, indium tin oxide (ITTiO) containing titanium oxide, and indium tin oxide (ITMO) containing molybdenum; and metals, such as gold, silver, and platinum, and alloys thereof.

The organic EL layer 230 is a laminate including various organic thin films. In the illustrated example, the organic EL layer 230 includes a hole injection layer 230a, a hole transport layer 230b, a light emitting layer 230c, an electron transport layer 230d, and an electron injection layer 230e. The hole injection layer 230a is made from a hole injecting organic material (for example, a triphenylamine derivative) and is formed in order to improve the efficiency of hole injection from the anode. The hole transport layer 230b is made of, for example, copper phthalocyanine. The light emitting layer 230c is made from a light emitting organic substance (for example, anthracene, bis[N-(1-naphthyl)-N-phenyl] benzidine, or N, N′-diphenyl-N—N-bis(1-naphthyl)-1,1′-(biphenyl)-4,4′-diamine (NPB)). The electron transport layer 230d is made from, for example, an 8-quinolinol aluminum complex. The electron injection layer 230e is made from an electron injecting material (for example, a perylene derivative or lithium fluoride), and is formed in order to improve the efficiency of electron injection from a cathode. The organic EL layer 230 is not limited to the illustrated example, and may include any appropriate combination of layers that causes light emission through recombination of electrons and holes in the light emitting layer 230c. The organic EL layer 230 is preferably as thin as possible because the organic EL layer 230 preferably transmits as much emitted light as possible. The organic EL layer 230 may be a very thin laminate having a thickness of, for example, from 5 nm to 200 nm, preferably about 10 nm.

The second electrode 240 typically functions as a cathode. In this case, a material having a low work function value is preferred as the material of the second electrode from the viewpoint of facilitating electron injection. Specific examples of this material include aluminum, magnesium, and alloys of aluminum and magnesium.

The sealing layer 250 is made from any appropriate material. The material of the sealing layer 250 preferably has an excellent barrier property and transparency. Typical examples of the material of the sealing layer include epoxy resin and polyurea. In one embodiment, the sealing layer 250 may be formed by applying epoxy resin (typically an epoxy resin adhesive), and bonding a barrier sheet to the applied epoxy resin.

C. First Retardation Layer

The first retardation layer 10 described above preferably shows a refractive index characteristic of nz>nx≥ny. A retardation Rth(550) in a thickness direction of the first retardation layer is preferably from −260 nm to −10 nm, more preferably from −230 nm to −15 nm, still more preferably from −215 nm to −20 nm.

In one embodiment, the refractive index of the first retardation layer has a relationship of nx=ny. The relationship “nx=ny” herein encompasses not only a case in which nx and ny are strictly equal to each other but also a case in which nx and ny are substantially equal to each other. Specifically, this means that Re(550) is less than 10 nm. In another embodiment, the refractive index of the first retardation layer has a relationship of nx>ny. In this case, an in-plane retardation Re(550) of the second retardation layer is preferably from 10 nm to 150 nm, more preferably from 10 nm to 80 nm.

When the relationship of the refractive index is nx>ny, the first retardation layer has a slow axis. A slow axis direction of the first retardation layer in this case may be adjusted so that a laminate of the first retardation layer and the second retardation layer has the desired in-plane retardation based on the in-plane retardation of the first retardation layer and the in-plane retardation of the second retardation layer.

The first retardation layer may be formed from any appropriate material. The first retardation layer is preferably a liquid crystal layer fixed in a homeotropic alignment. A liquid crystal material (liquid crystal compound) to be aligned in a homeotropic alignment may be a liquid crystal monomer or a liquid crystal polymer. A liquid crystal compound and forming method described in paragraphs [0020] to [0042] of Japanese Patent Application Laid-open No. 2002-333642 are given as a specific example of the liquid crystal compound and a method of forming the liquid crystal layer. A thickness of the first retardation layer in this case is preferably from 0.1 μm to 5 μm, more preferably from 0.2 μm to 3 μm.

Another favorable specific example of the first retardation layer is a retardation film described in Japanese Patent Application Laid-open No. 2012-32784 and formed from fumarate diester-based resin. A thickness of the first retardation layer in this case is preferably from 5 μm to 50 μm, more preferably from 10 μm to 35 μm.

D. Second Retardation Layer

The second retardation layer 20 preferably shows a refractive index characteristic of nx>ny≥nz. The in-plane retardation Re(550) of the second retardation layer is preferably from 80 nm to 200 nm, more preferably from 100 nm to 180 nm, still more preferably from 110 nm to 170 nm.

The second retardation layer shows so-called reverse wavelength dispersion dependency. Specifically, its in-plane retardations satisfy a relationship of Re(450)<Re(550). When such relationship is satisfied, an excellent reflection hue can be achieved. A ratio “Re(450)/Re(550)” is preferably 0.8 or more and less than 1, more preferably 0.8 or more and 0.95 or less.

The Nz coefficient of the second retardation layer is preferably from 1 to 3, more preferably from 1 to 2.5, still more preferably from 1 to 1.5, particularly more preferably from 1 to 1.3. When such relationship is satisfied, a more excellent reflection hue can be achieved.

The thickness of the second retardation layer may be set so that the desired in-plane retardation may be obtained. The thickness of the second retardation layer is preferably from 20 μm to 80 μm, more preferably from 40 μm to 60 μm.

The second retardation layer has a water absorption ratio of 3% or less, preferably 2.5% or less, more preferably 2% or less. When such water absorption ratio is satisfied, changes in display characteristics over time can be suppressed. The water absorption ratio may be determined in conformity to JIS K 7209.

The second retardation layer has a slow axis. An angle formed by the slow axis of the second retardation layer and the absorption axis of the polarizer is preferably from 38° to 52°, more preferably from 42° to 48°, still more preferably about 45°. With such angle, an extremely excellent antireflection characteristic can be achieved.

The second retardation layer is typically a retardation film formed of any appropriate resin. A polycarbonate-based resin is preferably used as the resin forming the retardation film. Details about the polycarbonate-based resin and specific examples thereof are described in, for example, Japanese Patent Application Laid-open No. 2014-026266. The description of the laid-open publication is incorporated herein by reference.

The second retardation layer 20 is obtained by, for example, stretching a film formed from the polycarbonate-based resin. Any appropriate forming method may be adopted as a method of forming a film from the polycarbonate-based resin. Specific examples thereof include a compression molding method, a transfer molding method, an injection molding method, an extrusion method, a blow molding method, a powder forming method, a FRP molding method, a cast coating method (such as a casting method), a calendering method, and a hot-press method. Of those, an extrusion method or a cast coating method is preferred. This is because the extrusion method or the cast coating method can increase the smoothness of the film to be obtained and provide satisfactory optical uniformity. Forming conditions may be appropriately set depending on, for example, the composition and kind of the resin to be used, and the desired characteristics of the retardation layer. For the polycarbonate-based resin, many film products are commercially available, and hence the commercially available films may each be subjected to stretching treatment.

The thickness of the resin film (unstretched film) may be set to any appropriate value depending on, for example, the desired thickness and desired optical characteristics of the retardation layer, and stretching conditions to be described later. The thickness is preferably from 50 μm to 300 μm.

Any appropriate stretching method and stretching conditions (such as a stretching temperature, a stretching ratio, and a stretching direction) may be adopted for the stretching. Specifically, one kind of various stretching methods, such as free-end stretching, fixed-end stretching, free-end shrinkage, and fixed-end shrinkage, may be employed alone, or two or more kinds thereof may be employed simultaneously or sequentially. With regard to the stretching direction, the stretching may be performed in various directions or dimensions, such as a lengthwise direction, a widthwise direction, a thickness direction, and an oblique direction. When the glass transition temperature of the resin film is represented by Tg, the stretching temperature falls within a range of preferably from Tg−30° C. to Tg+60° C., more preferably from Tg−10° C. to Tg+50° C.

A retardation film having the desired optical characteristics (such as a refractive index characteristic, an in-plane retardation, and an Nz coefficient) can be obtained by appropriately selecting the stretching method and stretching conditions.

In one embodiment, the retardation film is produced by subjecting a resin film to uniaxial stretching or fixed-end uniaxial stretching. The fixed-end uniaxial stretching is specifically, for example, a method involving stretching the resin film in its widthwise direction (lateral direction) while running the film in its lengthwise direction. The stretching ratio is preferably from 1.1 times to 3.5 times.

In another embodiment, the retardation film may be produced by continuously subjecting a resin film having an elongate shape to oblique stretching in the direction of a predetermined angle θ with respect to a lengthwise direction. When the oblique stretching is adopted, a stretched film having an elongate shape and having an alignment angle that is the angle θ with respect to the lengthwise direction of the film (having a slow axis in the direction of the angle θ) is obtained, and for example, roll-to-roll operation can be performed in its lamination with the polarizer. As a result, the manufacturing process can be simplified. The angle θ may be an angle formed by the absorption axis of the polarizer and the slow axis of the second retardation layer.

As a stretching machine to be used for the oblique stretching, for example, there is given a tenter stretching machine capable of applying feeding forces, or tensile forces or take-up forces, having different speeds on left and right sides in a lateral direction and/or a longitudinal direction. Examples of the tenter stretching machine include a lateral uniaxial stretching machine and a simultaneous biaxial stretching machine, and any appropriate stretching machine may be used as long as the resin film having an elongate shape can be continuously subjected to the oblique stretching.

Through appropriate control of each of the speeds on the left and right sides in the stretching machine, a second retardation layer (substantially a retardation film having an elongate shape) having the desired in-plane retardation and having a slow axis in the desired direction can be obtained.

The stretching temperature of the film may be changed depending on, for example, the desired in-plane retardation value and thickness of the second retardation layer, the kind of the resin to be used, the thickness of the film to be used, and a stretching ratio. Specifically, the stretching temperature is preferably from Tg−30° C. to Tg+30° C., more preferably from Tg−15° C. to Tg+15° C., most preferably from. Tg−10° C. to Tg+10° C. When the film is stretched at such temperature, a second retardation layer having appropriate characteristics can be obtained. Tg refers to the glass transition temperature of a constituent material for the film.

E. Laminate of First Retardation Layer and Second Retardation Layer

The in-plane retardation Re(550) of the laminate of the first retardation layer and the second retardation layer is from 120 nm to 142 nm or from 151 nm to 160 nm as described above. The initial reflection hue (typically, the initial values a₀ and b₀ of the value “a” and the value “b”) can be set to a hue shifted from a neutral hue toward blue or red by setting the in-plane retardation of the laminate within this range. A change in reflection hue in a high-temperature and high-humidity environment is consequently made unnoticeable as described above. The in-plane retardation of the laminate may be the in-plane retardation of the second retardation layer when the first retardation layer has a refractive index characteristic of nx=ny. When the first retardation layer has a refractive index characteristic pf nx>ny, the in-plane retardation of the laminate may be controlled by adjusting the in-plane retardation of the first retardation layer and/or the in-plane retardation of the second retardation layer, and an angle between the slow axis of the first retardation layer and the slow axis of the second retardation layer. The retardation Rth(550) in a thickness direction of the laminate is from 40 nm to 100 nm, preferably from 60 nm to 80 nm.

F. Polarizer

Any appropriate polarizer may be adopted as the polarizer 30. For example, a resin film forming the polarizer may be a single-layer resin film, or may be a laminate of two or more layers.

Specific examples of the polarizer including a single-layer resin film include: a polarizer obtained by subjecting a hydrophilic polymer film, such as a polyvinyl alcohol (PVA)-based film, a partially formalized PVA-based film, or an ethylene-vinyl acetate copolymer-based partially saponified film, to dyeing treatment with a dichroic substance, such as iodine or a dichroic dye, and stretching treatment; and a polyene-based alignment film, such as a dehydration-treated product of PVA or a dehydrochlorination-treated product of polyvinyl chloride. A polarizer obtained by dyeing the PVA-based film with iodine and uniaxially stretching the resultant is preferably used because the polarizer is excellent in optical characteristics.

The dyeing with iodine is performed by, for example, immersing the PVA-based film in an aqueous solution of iodine. The stretching ratio of the uniaxial stretching is preferably from 3 times to 7 times. The stretching may be performed after the dyeing treatment, or may be performed while the dyeing is performed. In addition, the dyeing may be performed after the stretching has been performed. The PVA-based film is subjected to swelling treatment, cross-linking treatment, washing treatment, drying treatment, or the like as required. For example, when the PVA-based film is immersed in water to be washed with water before the dyeing, contamination or an antiblocking agent on the surface of the PVA-based film can be washed off. In addition, the PVA-based film is swollen and hence dyeing unevenness or the like can be prevented.

The polarizer obtained by using the laminate is specifically, for example, a polarizer obtained by using a laminate of a resin substrate and a PVA-based resin layer (PVA-based resin film) laminated on the resin substrate, or a laminate of a resin substrate and a PVA-based resin layer formed on the resin substrate through application. The polarizer obtained by using the laminate of the resin substrate and the PVA-based resin layer formed on the resin substrate through application may be produced by, for example, a method involving: applying a PVA-based resin solution onto the resin substrate; drying the solution to form the PVA-based resin layer on the resin substrate, to thereby provide the laminate of the resin substrate and the PVA-based resin layer; and stretching and dyeing the laminate to turn the PVA-based resin layer into the polarizer. In this embodiment, the stretching typically includes the stretching of the laminate under a state in which the laminate is immersed in an aqueous solution of boric acid. The stretching may further include the aerial stretching of the laminate at high temperature (e.g., 95° C. or more) before the stretching in the aqueous solution of boric acid as required. The resultant laminate of the resin substrate and the polarizer may be used as it is (i.e., the resin substrate may be used as a protective layer for the polarizer). Alternatively, a product obtained as described below may be used: the resin substrate is peeled from the laminate of the resin substrate and the polarizer, and any appropriate protective layer in accordance with purposes is laminated on the peeling surface. Details about such method of producing a polarizer are described in, for example, JP2012-73580A. The entire description of the laid-open publication is incorporated herein by reference.

The thickness of the polarizer is preferably 25 μm or less, more preferably from 1 μm to 12 μm, still more preferably from 3 μm to 12 μm, particularly preferably from 3 μm to 8 μm. When the thickness of the polarizer falls within such range, curling at the time of heating can be satisfactorily suppressed, and satisfactory appearance durability at the time of heating is obtained.

The polarizer preferably shows absorption dichroism at any wavelength in the wavelength range of from 380 nm to 780 nm. The single layer transmittance of the polarizer is from 42.0% to 46.0%, preferably from 44.5% to 46.0%. The polarization degree of the polarizer is preferably 97.0% or more, more preferably 99.0% or more, still more preferably 99.9% or more.

G. Protective Layer

The protective layer is formed of any appropriate film that may be used as a protective layer fora polarizer. A material serving as a main component of the film is specifically, for example: a cellulose-based resin, such as triacetylcellulose (TAC); a transparent resin, such as a polyester-based, polyvinyl alcohol-based, polycarbonate-based, polyamide-based, polyimide-based, polyether sulfone-based, polysulfone-based, polystyrene-based, polynorbornene-based, polyolefin-based, (meth)acrylic, or acetate-based transparent resin; or a thermosetting resin or a UV-curable resin, such as a (meth)acrylic, urethane-based, (meth)acrylic urethane-based, epoxy-based, or silicone-based thermosetting resin or UV-curable resin. A further example thereof is a glassy polymer, such as a siloxane-based polymer. In addition, a polymer film described in JP 2001-343529A (WO 01/37007 A1) may be used. For example, a resin composition containing a thermoplastic resin having a substituted or unsubstituted imide group on a side chain thereof, and a thermoplastic resin having a substituted or unsubstituted phenyl group and a nitrile group on side chains thereof may be used as the material for the film, and the composition is, for example, a resin composition containing an alternating copolymer formed of isobutene and N-methylmaleimide, and an acrylonitrile-styrene copolymer. The polymer film may be, for example, an extrudate of the resin composition.

When the viewer-side protective layer is to be placed, the viewer-side protective layer may be subjected to surface treatment, such as hard coat treatment, antireflection treatment, anti-sticking treatment, or antiglare treatment, as required.

When the inner protective layer is to be placed, the inner protective layer is preferably optically isotropic. The phrase “be optically isotropic” as used herein refers to having an in-plane retardation Re(550) of from 0 nm to 10 nm and a thickness direction retardation Rth(550) of from −10 nm to +10 nm.

Each protective layer may have any appropriate thickness. The protective layer has a thickness of, for example, from 15 μm to 45 μm, preferably from 20 μm to 40 μm. In the case of a protective layer subjected to surface treatment, the thickness of the protective layer includes the thickness of the surface treatment layer.

### EXAMPLES

The present invention is specifically described below byway of Examples. However, the present invention is not limited by these Examples. Methods of measuring respective characteristics are as described below.

(1) Thickness

Measurement was performed with a digital micrometer (KC-351C manufactured by Anritsu Corporation).

(2) Retardation Value of Retardation Layer

A sample of 50 mm×50 mm was cut out of the retardation layer used in each of Examples and Comparative Examples, and was used as a measurement sample. For the produced measurement sample, an in-plane retardation was measured with a retardation measurement apparatus manufactured by Oji Scientific Instruments Co., Ltd. (product name: “KOBRA-WPR”). A measurement wavelength for the in-plane retardation was 550 nm, and a measurement temperature was 23° C.

(3) Value “a” and Value “b”

A black image was displayed on image display apparatus obtained in Examples and Comparative Examples to measure the value a₀ and the value b₀ with the use of “EZContrast 160D”, which is the name of a product manufactured by ELDIM. A value a₁ and a value b₁ were further measured in the same manner as the one described above, after the image display apparatus were left in an oven set to 65° C. and an RH of 90% for 250 hours. A value a₂ and a value b₂ were separately measured in the same manner as the one described above, after the image display apparatus were left in an oven set to 85° C. for 250 hours. The measurement was taken in three places of each image display apparatus, which are a central portion (measurement point 1) and right corner portions (two places in total of an upper right corner portion and a lower right corner portion: measurement points 2 and 3).

(4) Change in Reflection Hue

On organic EL display apparatus obtained in Examples and Comparative Examples, a change in reflection hue before and after the heating and humidification test of (3) at 65° C. and an RH of 90% was visually checked. Evaluation criteria are as follows.

∘: Change in reflection hue was unnoticeable

x: Change in reflection hue was conspicuous

### Reference Example 1: Production of Polarizer

An amorphous polyethylene terephthalate (A-PET) film (manufactured by Mitsubishi Plastics, Inc., product name: NOVACLEAR SH046, thickness: 200 μm) was prepared as a substrate, and its surface was subjected to corona treatment (58 W/m²/min). Meanwhile, PVA (polymerization degree: 4,200, saponification degree: 99.2%) having added thereto 1 wt % of acetoacetyl-modified PVA (manufactured by the Nippon Synthetic Chemical Industry Co. Ltd., product name: Gohsefimer 2200, polymerization degree: 1,200, saponification degree: 99.0% or more, acetoacetyl modification degree: 4.6%) was prepared, and applied so as to have a film thickness after drying of 12 μm, followed by drying under a 60° C. atmosphere by hot-air drying for 10 minutes to produce a laminate in which a PVA-based resin layer was formed on the substrate. Then, the laminate was first stretched in air at 130° C. at a ratio of 2.0 times to provide a stretched laminate. Next, there was performed a step of insolubilizing the PVA-based resin layer containing aligned PVA molecules included in the stretched laminate by immersing the stretched laminate in an insolubilizing aqueous solution of boric acid having a liquid temperature of 30° C. for 30 seconds. In the insolubilizing aqueous solution of boric acid of this step, the boric acid content was set to 3 wt % with respect to 100 wt % of water. The resultant stretched laminate was dyed to produce a colored laminate. The colored laminate is a product obtained by immersing the stretched laminate in a dyeing liquid having a liquid temperature of 30° C. and containing iodine and potassium iodide, to thereby adsorb iodine onto the PVA-based resin layer included in the stretched laminate. An iodine concentration and an immersion time were adjusted so that the polarizer to be obtained had a single layer transmittance of 44.5%. Specifically, in the dyeing liquid, water was used as a solvent, the iodine concentration was set to fall within the range of from 0.08 wt % to 0.25 wt %, and the potassium iodide concentration was set to fall within the range of from 0.56 wt % to 1.75 wt %. A ratio between the concentrations of iodine and potassium iodide was 1 to 7. Next, there was performed a step of subjecting the PVA molecules of the PVA-based resin layer onto which iodine had been adsorbed to cross-linking treatment by immersing the colored laminate in a cross-linking aqueous solution of boric acid at 30° C. for 60 seconds. In the cross-linking aqueous solution of boric acid of this step, the boric acid content was set to 3 wt % with respect to 100 wt % of water, and the potassium iodide content was set to 3 wt % with respect to 100 wt % of water. Further, the resultant colored laminate was stretched in an aqueous solution of boric acid at a stretching temperature of 70° C. at a ratio of 2.7 times in the same direction as that of the stretching in the air, resulting in a final stretching ratio of 5.4 times. Thus, a laminate of “substrate/polarizer” (thickness: 5 μm) was obtained. In the aqueous solution of boric acid of this step, the boric acid content was set to 6.5 wt % with respect to 100 wt % of water, and the potassium iodide content was set to 5 wt % with respect to 100 wt % of water. The resultant laminate was taken out from the aqueous solution of boric acid, and boric acid adhering to the surface of the polarizer was washed off with an aqueous solution having a potassium iodide content of 2 wt % with respect to 100 wt % of water. The washed laminate was dried with warm air at 60° C.

### Reference Example 2: Production of First Retardation Layer

A liquid crystal application liquid was prepared by dissolving, in 200 parts by weight of cyclopentanone, 20 parts by weight of a side chain-type liquid crystal polymer represented by Chemical Formula 1 (numbers “65” and “35” in the formula indicate the molar percentages of monomer units, and the monomer units are expressed as a block polymer body for the sake of convenience: a weight-average molecular weight of 5,000), 80 parts by weight of a polymerizable liquid crystal (manufactured by BASF SE, product name: “Paliocolor LC242”) exhibiting a nematic liquid crystal phase, and 5 parts by weight of a photopolymerization initiator (manufactured by Ciba Specialty Chemicals, product name: “Irgacure 907”). The application liquid was applied with a bar coater to a substrate film (norbornene-based resin film, manufactured by Zeon Corporation, product name: “ZEONEX”). The substrate film was then heated and dried at 80° C. for 4 minutes to align the liquid crystal. The resultant liquid crystal layer was irradiated with an ultraviolet ray and consequently cured, to thereby form a fixed liquid crystal layer (thickness: 0.58 μm) that serves as the first retardation layer on the substrate. This layer had Re(550) of 0 nm and Rth(550) of −71 nm, and had a refractive index characteristic of nz>nx=ny.

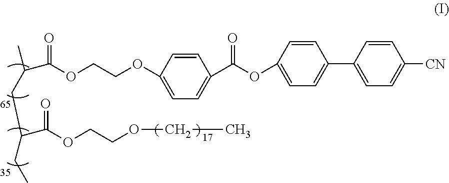

### Reference Example 3: Production of Retardation Film Constituting Second Retardation Layer

### 1-1. Production of Polycarbonate Resin Film

26.2 Parts by mass of isosorbide (ISB), 100.5 parts by mass of 9,9-[4-(2-hydroxyethoxy)phenyl]fluorene (BHEPF), 10.7 parts by mass of 1,4-cyclohexanedimethanol (1,4-CHDM), 105.1 parts by mass of diphenyl carbonate (DPC), and 0.591 part by mass of cesium carbonate (0.2 mass % aqueous solution) serving as a catalyst were each loaded into a reaction vessel. Under a nitrogen atmosphere, as a first step of a reaction, the heating medium temperature of the reaction vessel was set to 150° C. and the raw materials were dissolved while being stirred as required (about 15 minutes).

Then, the pressure in the reaction vessel was changed from normal pressure to 13.3 kPa, and while the heating medium temperature of the reaction vessel was increased to 190° C. in 1 hour, generated phenol was taken out of the reaction vessel.

The temperature in the reaction vessel was kept at 190° C. for 15 minutes. After that, as a second step, the pressure in the reaction vessel was set to 6.67 kPa, the heating medium temperature of the reaction vessel was increased to 230° C. in 15 minutes, and generated phenol was taken out of the reaction vessel. As the stirring torque of the stirrer increased, the temperature was increased to 250° C. in 8 minutes, and in order to remove generated phenol, the pressure in the reaction vessel was reduced to 0.200 kPa or less. After the stirring torque reached a predetermined value, the reaction was terminated, and the reaction product was extruded into water and then pelletized to provide a polycarbonate resin having the following composition: BHEPF/ISB/1,4-CHDM=47.4 mol %/37.1 mol %/15.5 mol %.

The resultant polycarbonate resin had a glass transition temperature of 136.6° C. and a reduced viscosity of 0.395 dL/g.

The resultant polycarbonate resin was vacuum-dried at 80° C. for 5 hours, and then a polycarbonate resin film having a thickness of 120 μm was produced using a film-forming apparatus with a single-screw extruder (manufactured by Isuzu Kakoki, screw diameter: 25 mm, cylinder preset temperature: 220° C.), a T-die (width: 200 mm, preset temperature: 220° C.), a chill roll (preset temperature: 120° C. to 130° C.), and a take-up unit.

1-2. Production of Retardation Film

The resultant polycarbonate resin filmwas laterally stretched with the use of a tenter stretching machine to provide a retardation film having a thickness of 50 μm. In this case, the stretching ratio was 250%, and the stretching temperature was set to from 137° C. to 139° C.

The resultant retardation film had an Re(550) of from 137 nm to 147 nm and Re(450)/Re(550) was 0.89.

### Example 1

1-1. Production of Polarizing Plate with Retardation Layer

The retardation film (second retardation layer) obtained in Reference Example 3 was bonded, via a PVA-based adhesive, to a surface of the polarizer of the substrate-polarizer laminate obtained in Reference Example 1. The retardation film and the polarizer were bonded so that an angle between the absorption axis of the polarizer and the slow axis of the second retardation layer (retardation film) is 45 degrees. The A-PET film (the substrate) was peeled from the laminate, and an acrylic film having a thickness of 40 μm was bonded via a PVA-based adhesive to a surface from which the A-PET film was peeled, to thereby obtain a laminate that had a protective layer-polarizer-second retardation layer configuration. The fixed liquid crystal layer (first retardation layer) was transferred to a surface of the second retardation layer of the laminate from the substrate-fixed liquid crystal layer (first retardation layer) laminate obtained in Reference Example 2. As a result, a polarizing plate with a retardation layer that had a protective layer-polarizer-second retardation layer-first retardation layer configuration was obtained. A laminate of the first retardation layer and the second retardation layer were separately produced and measured for its in-plane retardation Re(550). The measured in-plane retardation Re(550) was 151 nm.

1-2. Production of Organic EL Display Apparatus

An organic EL panel was taken out from an organic EL display apparatus (manufactured by Samsung Electronics, product name: “Galaxy 5”). A polarization film bonded to the organic EL panel was peeled and the polarizing plate with a retardation layer obtained in the step 1-1 was bonded in place of the polarization film to obtain an organic EL display apparatus. The values a₀ and b₀ of the obtained organic EL display apparatus were as shown in Table 1. The values a₁ and a₂ and b₁ and b₂ of the organic EL display apparatus after a heating and/or humidification test were as shown in Table 1. The obtained organic EL display apparatus was subjected to the evaluation of (4). The result of the evaluation is shown in Table 1 as well.

### Example 2

An organic EL display apparatus was obtained in the same manner as the one in Example 1, except that a₀ and b₀ were set to values shown in Table 1 by making an adjustment so that the in-plane retardation Re(550) of a laminate of the first retardation layer and the second retardation layer was 142 nm. The obtained organic EL display apparatus was subjected to the evaluation of (4). The result of the evaluation is shown in Table 1 as well.

### Comparative Example 1

An organic EL display apparatus was obtained in the same manner as the one in Example 1, except that a₀ and b₀ were set to values shown in Table 1 by making an adjustment so that the in-plane retardation Re(550) of a laminate of the first retardation layer and the second retardation layer was 147 nm. The obtained organic EL display apparatus was subjected to the evaluation of (4). The result of the evaluation is shown in Table 1 as well.

### Comparative Example 2

An organic EL display apparatus was obtained in the same manner as the one in Example 1, except that a₀ and b₀ were set to values shown in Table 1 by making an adjustment so that the in-plane retardation Re(550) of a laminate of the first retardation layer and the second retardation layer was 149 nm. The obtained organic EL display apparatus was subjected to the evaluation of (4). The result of the evaluation is shown in Table 1 as well.

TABLE 1

| | Re | | | | | | | | | | | | Hue |
|---|---|---|---|---|---|---|---|---|---|---|---|---|---|
| | (550) | Point | a₀ | b₀ | a₁ | a₂ | b₁ | b₂ | a₀ × a₁ | a₀ × a₂ | b₀ × b₁ | b₀ × b₂ | change |
| Example 1 | 151 | 1 | −2.52 | −2.11 | −3.15 | −2.98 | −2.35 | −2.54 | 7.91 | 7.50 | 4.95 | 5.36 | ∘ |
| | | 2 | −2.55 | −2.20 | −1.49 | −2.76 | −0.95 | −2.33 | 3.79 | 7.03 | 2.08 | 5.12 | |
| | | 3 | −2.34 | −2.02 | −1.75 | −2.59 | −1.10 | −2.28 | 4.08 | 6.06 | 2.21 | 4.59 | |
| Example 2 | 142 | 1 | 1.47 | −0.08 | 0.63 | 1.24 | −0.28 | −0.28 | 0.92 | 1.82 | 0.02 | 0.02 | ∘ |
| | | 2 | 1.58 | −0.08 | 1.74 | 1.13 | −0.37 | −0.34 | 2.75 | 1.79 | 0.03 | 0.03 | |
| | | 3 | 1.65 | −0.10 | 1.94 | 1.18 | −0.44 | −0.43 | 3.19 | 1.95 | 0.04 | 0.04 | |
| Comparative | 147 | 1 | −0.62 | −1.29 | −1.02 | −1.51 | −1.47 | −1.70 | 0.63 | 0.94 | 1.88 | 2.18 | x |
| Example 1 | | 2 | −0.54 | −1.23 | 0.17 | −0.96 | −0.49 | −0.99 | −0.09 | 0.51 | 0.60 | 1.21 | |
| | | 3 | −0.39 | −1.10 | 0.38 | −0.96 | −0.36 | −1.03 | −0.14 | 0.37 | 0.39 | 1.13 | |
| Comparative | 149 | 1 | −0.48 | −0.48 | −1.12 | −1.53 | −0.81 | −1.19 | 0.54 | 0.74 | 0.38 | 0.57 | x |
| Example 2 | | 2 | −0.41 | −0.47 | 0.72 | −1.43 | 0.19 | −0.97 | −0.29 | 0.58 | −0.09 | 0.46 | |
| | | 3 | −0.38 | −0.45 | 0.29 | −1.30 | 0.02 | −0.72 | −0.11 | 0.49 | −0.01 | 0.32 | |

<Evaluation>

As is apparent from Table 1, according to Examples of the present invention, a change in hue can be made unnoticeable even after a heating and humidification test by setting the initial values a₀ and b₀ of the values a and b to values that are shifted from neutral points and that satisfy Expressions (1) and (2).

a₀×a₁>0 (1)

b₀×b₁>0 (2)

On the image display apparatus of Comparative Examples, which do not satisfy Expressions (1) and (2), a change in reflection hue is noticeable particularly in corner portions.

### INDUSTRIAL APPLICABILITY

The image display apparatus according to the present invention is favorably applicable to television sets, displays, cellular phones, mobile information terminals, digital cameras, video cameras, portable game machines, car navigation systems, copying machines, printers, fax machines, watches and clocks, microwave ovens, and the like.

### REFERENCE SIGNS LIST

10 first retardation layer
20 second retardation layer
30 polarizer
40 moisture-barrier layer
200 organic EL cell
300 organic EL display apparatus

1. An image display apparatus, comprising a display cell, a first retardation layer, a second retardation layer, and a polarizer, which are arranged in the stated order,
wherein Re(550) of a laminate of the first retardation layer and the second retardation layer is from 120 nm to 142 nm, or from 151 nm to 160 nm, and
wherein, when an initial value of a front reflection hue value “a” in a non-lit state is represented by a₀, a value of “a” after the image display apparatus is left in an environment set to 65° C. and an RH of 90% for 250 hours is represented by a₁, an initial value of a front reflection hue value “b” is represented by b₀, and a value of “b” after the image display apparatus is left in an environment set to 65° C. and an RH of 90% for 250 hours is represented by b₁, Expressions (1) and (2) are satisfied:
a₀×a₁>0 (1); and
b₀×b₁>0 (2).

2. The image display apparatus according to claim 1, further comprising a moisture-barrier layer on one side of the polarizer that is opposite from the second retardation layer.

3. The image display apparatus according to claim 1, wherein, when a value of the value “a” after the image display apparatus is left in an environment set to 85° for 250 hours is represented by a₂, and a value of the value “b” after the image display apparatus is left in an environment set to 85° for 250 hours is represented by b₂, Expressions (3) and (4) are satisfied:
a₀×a₂>0 (3); and
b₀×b₂>0 (4).

4. The image display apparatus according to claim 1, wherein the value a₀ is from −10.00 to −1.00, or from 1.00 to 10.00, and the value b₀ is from −10.00 to −1.50, or from −0.20 to 10.00.

5. The image display apparatus according to claim 1, wherein the first retardation layer shows a refractive index characteristic of nz>nx≥ny, and the second retardation layer shows a refractive index characteristic of nx>ny≥nz.

6. The image display apparatus according to claim 1, wherein the image display apparatus is an organic electroluminescence display apparatus.

7. An image display apparatus, comprising a display cell, a first retardation layer, a second retardation layer, and a polarizer, which are arranged in the stated order,
wherein Re(550) of a laminate of the first retardation layer and the second retardation layer is from 120 nm to 142 nm, or from 151 nm to 160 nm, and
wherein, when an initial value of a front reflection hue value “a” in a non-lit state is represented by a₀, a value of “a” after the image display apparatus is left in an environment set to 65° C. and an RH of 90% for 250 hours is represented by a₁, an initial value of a front reflection hue value “b” is represented by b₀, and a value of “b” after the image display apparatus is left in an environment set to 65° C. and an RH of 90% for 250 hours is represented by b₁, the value a₀ is from −10.00 to −1.00, or from 1.00 to 10.00, and the value b₀ is from −10.00 to −1.50, or from −0.20 to 10.00, and
wherein a front reflection hue in a perimeter portion satisfies Expressions (1) and (2):
a₀×a₁>0 (1); and
b₀×b₁>0 (2).
